(19) United States
(12) Patent Application Publication
(10) Pub. No.: US 2013/0087704 A1
(43) Pub. Date: Apr. 11, 2013

(54) GAS FIELD IONIZATION ION SOURCE, SCANNING CHARGED PARTICLE MICROSCOPE, OPTICAL AXIS ADJUSTMENT METHOD AND SPECIMEN OBSERVATION METHOD

(71) Applicant: Hitachi High-Technologies Corporation, Tokyo (JP)

(72) Inventors: Tohru ISHITANI, Hitachinaka (JP); Yoichi OSE, Mito (JP); Hiroyasu SHICHI, Tokyo (JP); Shinichi MATSUBARA, Komae (JP); Tomihiro HASHIZUME, Hiki-gun (JP); Muneyuki FUKUDA, Kokubunji (JP)

(73) Assignee: HITACHI HIGH-TECHNOLOGIES CORPORATION, Tokyo (JP)

(21) Appl. No.: 13/624,607

(22) Filed: Sep. 21, 2012

Related U.S. Application Data
(62) Division of application No. 12/314,553, filed on Dec. 12, 2008, now abandoned.

(30) Foreign Application Priority Data
Dec. 14, 2007 (JP) 2007-322703

(51) Int. Cl. H01J 37/285; H01J 27/26

(52) U.S. Cl. CPC H01J 37/285; H01J 27/26
USPC 250/307; 250/423 F; 250/306

(57) ABSTRACT

A gas field ionization ion source (GFIS) is characterized in that the aperture diameter of the extraction electrode can be set to any of at least two different values or the distance from the apex of the emitter to the extraction electrode can be set to any of at least two different values. In addition, solid nitrogen is used for cooling. It may be possible to not only let divergently emitted ions go through the aperture of the extraction electrode but also, in behalf of differential pumping, reduce the diameter of the aperture. In addition, it may be possible to reduce the physical vibration of the cooling means. Consequently, it may be possible to provide a highly stable GFIS and a scanning charged particle microscope equipped with such a GFIS.

### RELATED APPLICATIONS

This application is the U.S. National Phase under 35 U.S.C. §371 of International Application No. PCT/JP2011/064478, filed on Jun. 23, 2011, which in turn claims the benefit of Japanese Application No. 2010-151119, filed on Jul. 1, 2010, and Japanese Application No. 2010-238711, filed on Oct. 25, 2010, the disclosures of which Applications are incorporated by reference herein.

### BACKGROUND OF THE INVENTION

1. Field of the Invention

The present invention relates to charged particle microscopes for observing surfaces of such specimens as semiconductor devices and new materials. For example, the invention relates to a scanning charged particle microscope which uses light ions as charged particles for shallow surface observation of a specimen with a high resolution and a large depth of focus, and a gas field ionization ion source for generating ions therein.

2. Description of the Related Art

Non-Patent Document 1 describes a focused ion beam (abbreviated to FIB) apparatus which is equipped with a gas field ionization ion source (abbreviated to GFIS) and which uses hydrogen (H₂), helium (He), neon (Ne) or other gas ions. Unlike a gallium (Ga: metal) FIB formed from the liquid metal ion source (abbreviated to LMIS) which is used often these days, such a gas FIB does not contaminate the specimen with Ga. It is also described that since the energy spread of the gas ions extracted from a GFIS is narrow and the virtual source size of the GFIS is small, it is possible to form a smaller beam than the Ga-FIB. Especially, it is further disclosed that the GFIS can attain better ion source characteristics such as a higher angular current density if a fine projection (hereinafter denoted as nano tip) is formed at the apex of the emitter (or the atoms at the apex of the emitter are reduced to several or fewer atoms). The phenomenon that a nano tip at the apex of the ion emitter raises the angular ion current density is also disclosed in Non-Patent Documents 2 and 3 and Patent Document 1. Examples of fabricating such nano tips are disclosed in Patent Document 2 and Non-Patent Documents 3 and 4. In Patent Document 2, a nano tip is formed by field evaporation from the emitter material tungsten (W). In Non-Patent Documents 3 and 4, a nano tip is formed of a second material which is different from a first metal or the emitter material.

Each of Non-Patent Document 2 and Patent Document 2 discloses a scanning charged particle microscope provided with a GFIS which emits ions of the light element He. Considering irradiation particles in weight, a He ion is about 7000 times heavier than an electron and about 17 times lighter than a Ga ion. Therefore, the damage given to the specimen by a He ion, which is dependent upon the magnitude of the momentum transferred to atoms of the specimen, is a little larger than by an electron but greatly smaller than by a Ga ion. In addition, the secondary electron excitation regions resulting from irradiation particles penetrating into the specimen are more localized to the specimen surface as compared with those resulting from irradiation electrons. Due to this characteristic, imaging by the scanning ion microscope (abbreviated to SIM) is expected to be more highly sensitive to the specimen's surface information than the scanning electron microscope (abbreviated to SEM). Further from the viewpoint of microscopy, ion beam irradiation is characterized in that imaging can be done with a very large depth of focus since ions are so heavier than electrons that the diffraction effects during focusing of the ion beam is ignorable.

### [Patent Document 1)

JP-A-1983-85242

### [Patent Document 2]

JP-A-1995-192669 [Non-Patent Document 1]

K. Edinger, V. Yun, J. Meingailis, J. Orloff, and G. Magera, J. Vac. Sci. Technol. A 15 (No. 6) (1997) 2365 [Non-Patent Document 2]

J. Morgan, J. Notte, R. Hill, and B. Ward, Microscopy Today July 14 (2006) 24

### [Non-Patent Document 3]

H.-S. Kuo, I.-S. Hwang, T.-Y. Fu, Y-C. Lin, C.-C. Chang, and T. T. Tsong, 16th Int. Microscopy Congress (IMC16), Sapporo (2006) 112D

### [Non-Patent Document 4]

H.-S. Kuo, I.-S. Hwang, T.-Y. Fu, J.-Y. Wu, C.-C. Chang, and T. T. Tsong, Nano Letters 4 (2004) 2379.

### SUMMARY OF THE INVENTION

The inventors of the present application conducted assiduous investigations on the GFIS and consequently obtained the following knowledge.

Ideally, a nano tip is formed at the apex of a W emitter in the direction of the axial orientation <111>. To check the ion emission therefrom or align (adjust) this ion emission direction with the optical axis of the scanning ion microscope, a field ion microscope (abbreviated to FIM) pattern or corresponding means is used. In this pattern observation, it is preferable that the aperture diameter of the extraction electrode be large to such an extent that an ion beam with a divergence half angle a of about 20 degrees can go through the aperture. However, after the alignment (adjustment) with the optical axis, the pressure of the ion material gas (for example, He) which is introduced into the emitter room is raised to about 10⁻²-1 Pa in order to increase the angular ion current density (emitted ion current per unit solid angle). This introduced gas is released by differential pumping through the aperture of the extraction electrode. In order to keep high the gas molecule density around the tip of the emitter as well as to reduce the amount of gas evacuated without being ionized, the aperture diameter is preferred to be small. A first problem found by the inventors of the present application is to not only allow the aperture to let widely emitted ions go through but also secure the differential pumping although the former involves enlarging the aperture diameter while the latter involves reducing the aperture diameter. If the nano tip is damaged, the ion emission direction from the nano tip must be checked again after a nano tip is reformed.

To increase the ion current, it is important to increase the density of gas molecules around the tip.

Since the density n of gas molecules per unit pressure [Pa] is in inverse proportion to the gas temperature T[K] as given by the following formula, it is important to cool the gas and the emitter together.

n[molecules cm⁻³Pa⁻¹]=7.247×10¹⁶/T(K) (1)

The cooling means often includes a physically vibrating element and therefore may cause the emitter to vibrate. A second problem found by the inventors of the present application is to reduce this vibration of the emitter.

It is an object of the present invention to improve the stability of the gas field ionization ion source.

A GFIS of the present invention is characterized in that the aperture diameter of the extraction electrode can be set to any of two different values or the distance from the apex of the emitter to the extraction electrode can be set to any of two different values.

A GFIS of the present invention is characterized in that solid nitrogen is used for cooling.

According to the present invention, it is possible to not only let divergently emitted ions go through the aperture of the extraction electrode but also, in behalf of differential pumping, reduce the diameter of the aperture. It is also possible to reduce the physical vibration of the cooling means. Consequently, it is possible to provide a highly stable GFIS and a scanning charged particle microscope equipped with such a GFIS.

### BRIEF DESCRIPTION OF THE DRAWINGS

Other objects and advantages of the invention will become apparent from the following description of embodiments with reference to the accompanying drawings in which:

FIG. 1 schematically shows the configuration of a gas field ionization ion source (GFIS);

FIG. 2A is a diagram for explaining the relation between the emitter's tip and the hole diameter of the extraction electrode;

FIG. 2B is an example of a field ion microscope (abbreviated to FIM) pattern from the W emitter <111> before a nano tip is generated;

FIG. 3 shows an extraction electrode comprising a movable flat plate electrode which has dimensionally-different apertures formed in the same plane;

FIG. 4 shows aperture changing means comprising an aperture-forming part having an aperture through which ions extracted by the extraction electrode are passed, and a mounting part on which the aperture-forming part is mounted;

FIG. 5 shows an extraction electrode which can be moved in the direction of the optical axis;

FIG. 6 shows a gas field ionization ion source which uses solid nitrogen as the cooling substance;

FIG. 7 shows a gas field ionization ion source equipped with a refrigerator by which a cooling substance, obtained by solidifying a refrigerant gas, is further cooled;

FIG. 8 is an illustration for explaining an accelerating lens function between the extraction electrode and the focusing lens first electrode; and

FIG. 9 shows curves indicating how the angular magnification M_{ang} by the accelerating lens between the extraction electrode and the focusing lens first electrode is dependent on the extraction voltage Vₑₓₜ.

### DESCRIPTION OF THE PREFERRED EMBODIMENTS

One aspect of the present invention provides a gas field ionization ion source having a needle-shaped anode emitter and an extraction electrode which forms an electric field by which gas molecules at the apex of the emitter are ionized and extracted, wherein the diameter of the extraction electrode's aperture for letting extracted ions pass therethrough can be set to any of at least two different values.

Another aspect of the present invention provides a gas field ionization ion source having a needle-shaped anode emitter and an extraction electrode which forms an electric field by which gas molecules at the apex of the emitter are ionized and extracted, wherein the extraction electrode can be separated into an aperture-forming part having an aperture for letting extracted ions pass therethrough, and a base part on which the aperture-forming part is mounted, wherein the aperture-forming part can be withdrawn from and set around the optical axis of ions.

The aperture-forming part may be slid with respect to the base part.

Another aspect of the present invention provides a gas field ionization ion source having a needle-shaped anode emitter and an extraction electrode which forms an electric field by which gas molecules at the apex of the emitter are ionized and extracted, wherein the distance from the apex of the emitter to the extraction electrode can be set to any of at least two different values.

Another aspect of the present invention provides a gas field ionization ion source comprising: a needle-shaped anode emitter and an extraction electrode which forms an electric field by which gas molecules at the apex of the emitter are ionized and extracted, wherein the cooling substance for cooling the emitter is a solid-state substance obtained by solidifying a refrigerant gas which is in the gaseous state under room temperature and atmospheric pressure conditions. The refrigerant gas may be nitrogen.

Another aspect of the present invention provides a scanning charged particle microscope comprising: a gas field ionization ion source as described above; a lens system by which ions from the ion source are accelerated and focused on a specimen; a limiting apparatus plate for limiting the ions which are focused on the specimen; and a charged particle detector to detect charged particles emitted from the specimen.

Another aspect of the present invention provides a method for adjusting the optical axis of a scanning charged particle microscope as described above, wherein the angular range of emitted ions allowed to pass through the extraction electrode is set larger for adjusting the optical axis of the gas field ionization ion source but smaller than for adjusting the optical axis for using the scanning charged particle microscope to observe the specimen.

Another aspect of the present invention provides a method for observing a specimen by using a scanning charged particle microscope as described above, wherein the angular range of emitted ions allowed to pass through the extraction electrode is set larger for adjusting the optical axis of the gas field ionization ion source but smaller than for adjusting the optical axis for using the scanning charged particle microscope to observe the specimen.

Above-mentioned and other novel characteristics and effects of the present invention will be described below by way of embodiments with reference to the drawings. Note that the drawings are used for the purpose of description and do not intend to limit the scope of the claims. As well, some of the respective embodiments can be combined as appropriate.

### Embodiment 1

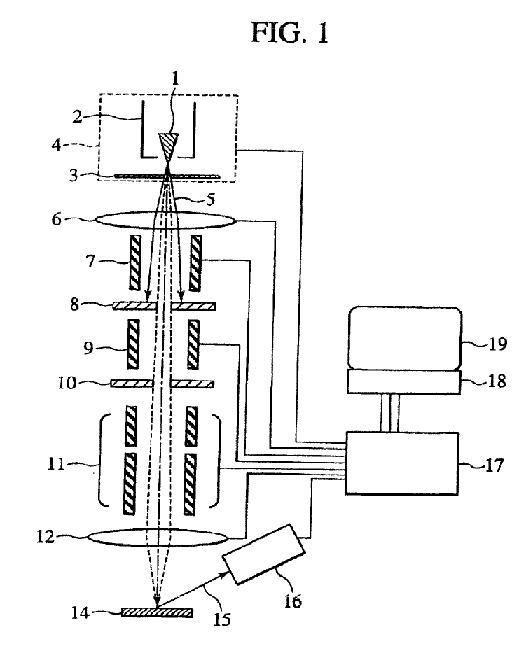

FIG. 1 schematically shows the construction of a scanning charged particle microscope equipped with a GFIS. The ions 5 emitted from the emitter 1 of the GFIS 4 are focused onto a specimen 14 by a focusing lens 6 and an objective lens 12. A beam deflector/aligner 7, a movable beam limiting aperture plate 8, a blanking electrode 9, a blank beam stop plate 10 and a beam deflector 11 are disposed between the two lenses. The secondary electrons 15 emitted from the specimen 14 are detected by a secondary electron detector 16. A beam controller 17 controls the GFIS 4, focusing lens 6, objective lens 12, upper beam deflector/aligner 7, lower beam deflector 11, secondary electron detector 16 and others. A personal computer 18 controls the beam controller 17 and processes/stores various data. An image display unit 19 displays SIM images and control screens of the PC 18.

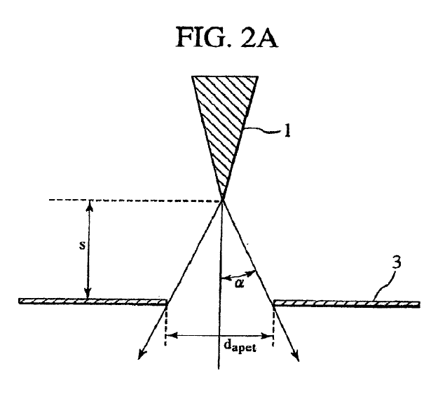

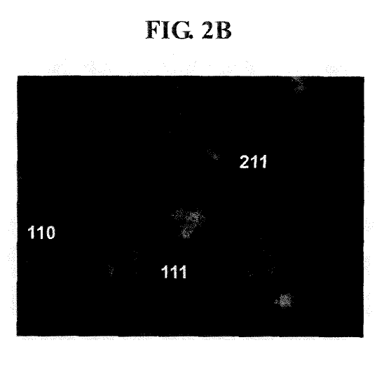

FIG. 2A is a diagram for explaining the relation between the emitter's tip and the hole diameter of the extraction electrode. FIG. 2B is an example of a field ion microscope (abbreviated to FIM) pattern from the W emitter <111> before a nano tip is generated. Major orientations <111> and <211> are marked on the pattern. A nano tip is formed in the direction of this <111> orientation. To verify this orientation of formation, it is preferable that observation of emitted ions be done so widely with respect to the orientation <111> as to make observable those emitted in the direction of the orientation <211> at least. Aperture angle θ between orientations <hk1> and <h′ k′ 1′> is calculated by using the following formula. Accordingly, θ between orientations <111> and <211> is calculated to be about 19.5 degrees.

$$cos θ = \frac{{hh}^{′} + {kk}^{′} + {ll}^{′}}{{( {h}^{2} + {k}^{2} + {l}^{2} )}^{1 / 2} {( {h}^{2} + {k}^{2} + {l}^{2} )}^{1 / 2}} \qquad ( 2 )$$

If the distance s from the emitter tip to the extraction electrode is 5 mm, the aperture diameter dₐₚₜᵤᵣₑ required is 2×5×tan19.5°=3.5 (mm). Since the ion emission divergence angle is narrowed to 1 degree or smaller after a nano tip is formed, the aperture diameter dₐₚₜᵤᵣₑ is sufficiently large if not smaller than 0.2 [mi]. To increase the radiant angular current density, ion material gas (for example, He) is introduced into the nano tip room to a degree of vacuum of approximately 10⁻²-10 Pa. Behind the extraction electrode, the ambience surrounding the focusing lens, objective lens and specimen is highly evacuated. In the aspect of differential pumping, dₐₚₜᵤᵣₑ=0.2 [mm] is valid.

The distance s is set by considering not only this ion emission divergence angle but also that excessively shortening the distance causes electric discharge between the emitter and the extraction electrode while excessively lengthening the distance causes collision between emitted ions and introduced He gas atoms (or molecules). This collision deteriorates the beam focusing characteristic of the scanning charged particle microscope since the traveling directions of emitted ions are bent and therefore the virtual source size of the ion source enlarges substantially. By using the gas molecule density n and diameter a, the mean free path A. of the emitted ions can be calculated from the following formula.

$$λ = √ 2 \frac{1}{n} πσ 2 \qquad ( 3 )$$

For He molecules (a-0.22 nm), the above formula is rewritten as below by denoting the gas temperature as T[K] and pressure as p [Pa].

Λ[cm]=6.4E−3(T/p) (4)

For example, if p=5Pa, X is 3.5 and 1.0 [mm] at room temperature (T=273K) and liquid nitrogen temperature (T=77K), respectively.

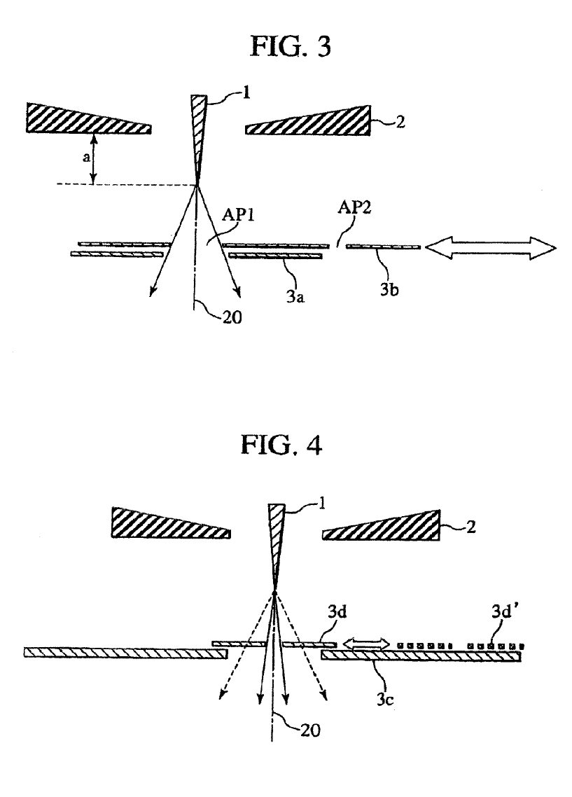

In the present embodiment, means to change the aperture diameter dₐₚₜᵤᵣₑ of the extraction electrode 3 is employed. Specifically, a fixed electrode 3a having a large aperture (for example 6 mm in diameter) is combined with a movable flat plate electrode 3b having two dimensionally-different apertures (dₐₚₜᵤᵣₑ=0.2 and 3.5 [mm]) formed in the same plane (Refer to FIG. 3). The center of the fixed electrode's large aperture is aligned with the optical axis 20 of the scanning charged particle microscope. Through moving operation from the atmospheric side, it is possible to move the movable flat plate electrode 3b while keeping the movable flat plate electrode 3b perpendicular to the optical axis. Thus, either of its large and small apertures can selectively be aligned with the optical axis. Although two dimensionally different apertures are available in the present embodiment, three or more holes may be prepared. Increasing the number of such dimensionally-different apertures directly widens the assortment of adjustment/choice for the differential pumping described later. Since high voltage is applied to the extraction electrode 3 when the GFIS is mounted to the scanning charged particle microscope, the movable flat plate electrode 3b is insulated from the microscope column (not shown in the figure) at the ground potential.

### Embodiment 2

The present embodiment described below is a scanning charged particle microscope provided with changing means to change the aperture diameter dₐₚₜᵤᵣₑ of the extraction electrode 3 which differs from the changing means employed in embodiment 1. The following description is focused on what are unique to the present embodiment.

The changing means of the present embodiment is structurally similar to the variable aperture employed in cameras and others. Plural diaphragm blades are combined so as to have a circular aperture which can coaxially be varied in diameter by changing the amount of overlap between diaphragm blades. By employing such means to change the aperture diameter of the extraction electrode, it is possible to not only let widely emitted ions go through but also, in behalf of differential pumping, reduce the diameter of the aperture.

### Embodiment 3

The present embodiment is a scanning charged particle microscope provided with changing means to change the aperture diameter dₐₚₑᵣₜᵤᵣₑ of the extraction electrode 3 which differs from the changing means employed in either embodiment 1 or 2. The following description is focused on what are unique to the present embodiment.

As shown in FIG. 4, the changing means of the present embodiment can be separated into an aperture-forming part 3d having an aperture through which ions extracted by the extraction electrode are passed, and a mounting part 3c on which the aperture-forming part 3d is mounted. The aperture-forming part 3d can be moved to and withdrawn from the optical axis 20. The aperture-forming part 3 is located as indicated with reference numeral 3d′ if the aperture-forming part 3 is withdrawn from the optical axis 20 by sliding it on the mounting part 3c.

### Embodiment 4

Like embodiments 1 through 3, the present embodiment intends to solve the problem of not only letting widely emitted ions go through but also, in behalf of differential pumping, reducing the diameter of the aperture. However, a different approach is taken by the present invention to solve the problem. Specifically, the extraction electrode 3 (dₐₚₜᵤᵣₑ=1 [MM]) is provided with means to move it in the axial direction. The following description is mainly focused on what are unique to the present embodiment.

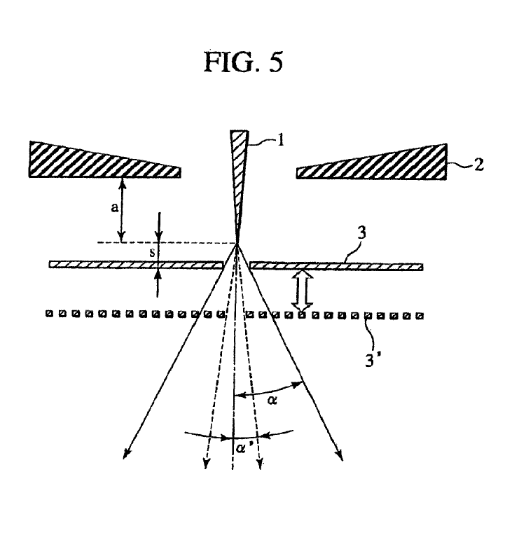

FIG. 5 schematically shows the extraction electrode which can be moved in the direction of the optical axis.

Reference numeral 3′ indicates the same extraction electrode after it is moved. Distance s from the emitter tip to the aperture of the extraction electrode can be set to any of two values 1 and 5 [mm]. s=1 mm corresponds to an ion emission divergence half angle a of about 27 degrees while s=5 mm to about 6 degrees. By thus moving the extraction electrode in the axial direction, it is possible to not only let widely emitted ions go through but also, in behalf of differential pumping, reduce the diameter of the aperture.

If the aperture diameter dₐₚₜᵤᵣₑ of the extraction electrode 3 is 1 [mm] in combination with s=1 mm, it is possible to it is possible to not only let widely emitted ions go through but also, in behalf of differential pumping, reduce the diameter of the aperture. However, discharge is likely to occur between the emitter tip and the extraction electrode if the pressure p of the ion material gas is raised in order to raise the brightness. S=5 mm is for preventing this discharge. However, if s is excessively large, ions emitted from the emitter may collide with gas molecules, which causes undesirable results such as deflected trajectories and reduced kinetic energies of ions. In addition, this change of s is accompanied by a change in the strength of the electric field formed at the tip of the emitter although the emitter potential is fixed.

Consequently, the ion current changes largely since the ionization efficiency changes. Therefore, to reduce the change of the ion current, there is provided a select mode for enabling/disabling adjustment of the extraction voltage.

Although the present embodiment changes the emitter tip-to-electrode distance s discontinuously to one of two values, namely 1 and 5 [mm], continuous change is preferable since continuous adjustment is possible. In addition, although the present embodiment changes the distance s to one of the two values by moving the extraction electrode in the axial direction, substantially the same effect can be obtained by moving the emitter in the axial direction with the extraction electrode fixed.

### Embodiment 5

To attain a high ion current, it is important to cool the ion material, i.e., introduced gas as well as the ion emitter. In the case of He gas, cooling down to about 10K is desirable. However, such a cooling device usually generates physical vibration and propagate it to the emitter. Vibration of the emitter causes the scanning charged particle microscope to vibrate the beam irradiation spot on the specimen, resulting in a lowered resolution of the microscope. It is difficult to stop the propagation of physical vibration from the cooling device to the emitter.

Accordingly, the present embodiment employs solid nitrogen (solidification point in vacuum: about 51K) as the cooling substance. The following description is focused on what are unique to the present embodiment.

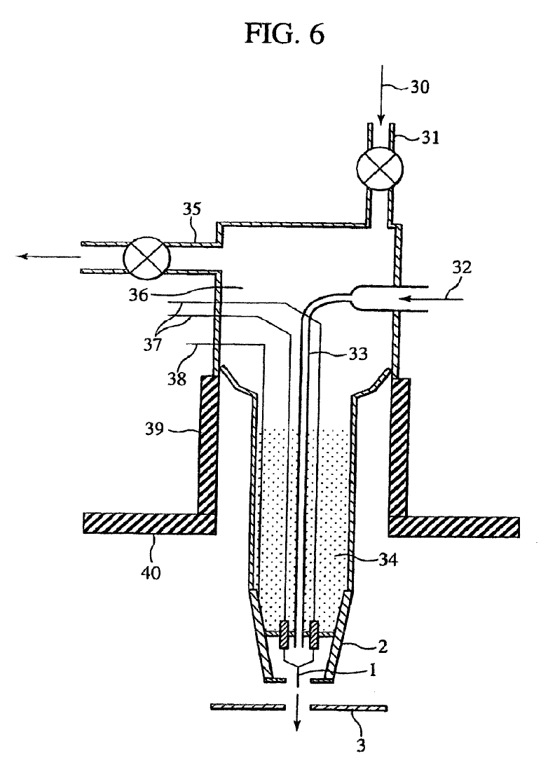

FIG. 6 schematically shows the construction of the ion source. Into the vicinity of the emitter 1, ion material gas, namely He gas 32 is introduced via a thin gas supply pipe 33. Solid nitrogen 34 is used as the cooling substance. Liquid nitrogen 30, firstly introduced into the refrigerant room 36 from a supply pipe 31, becomes solid nitrogen 34 since the vaporized nitrogen is evacuated through the exhaust pipe 35. The solid nitrogen in the evacuated environment cools the emitter and introduced gas as the solid nitrogen absorbs heat from them and sublimes. This is quite effective in lightening the vibration of the emitter tip since unlike liquid nitrogen, sublimation does not generate bubbles which cause physical vibration. To sufficiently cool the emitter, it is preferable to cool the emitter voltage application wire 37, the control electrode voltage application wire 38 and the extraction electrode 3. In addition, a low heat conduction material is used for junction between the cooled section and the room temperature section in behalf of radiation shield against inrushing heat from the room temperature section into the cooled section by thermal radiation. This cooling means is much more compact and inexpensive as compared with He cooling means aimed at cooling down to about 10K.

The cooling substance of the present embodiment is characterized in that it is obtained by solidifying a refrigerant gas which is in a gaseous state under room temperature and atmospheric pressure conditions. Accordingly, the refrigerant gas may be hydrogen (melting point 14K and boiling point 20K at atmospheric pressure), neon (melting point: 24K, boiling point: 27K), oxygen (melting point: 54K, boiling point 90K), argon (melting point: 84K, boiling point: 87K), methane (melting point: 90K, boiling point: 111K) or the like instead of nitrogen (melting point: 51K, boiling point 77K). In terms of cost and safety, nitrogen is superior.

### Embodiment 6

Although embodiment 5 uses a cooling substance obtained by converting a refrigerant gas into a solid state, such a solid cooling substance is further cooled in the present embodiment. The following description are focused on what are unique to the present embodiment.

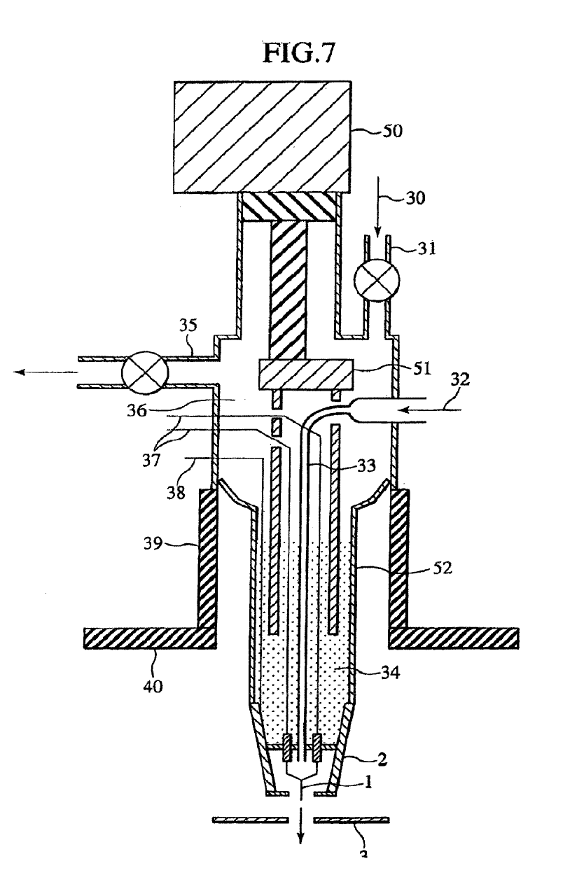

FIG. 7 schematically shows a gas field ionization ion source equipped with a refrigerator by which a solidified cooling substance is further cooled. The refrigerant gas in this example is nitrogen. Firstly, liquid nitrogen 30 is introduced into the cooling substance room 36 from the supply pipe 31. The cooling head 51 of the He refrigerator 50 is arranged within the .cooling substance room 36, and cooling metal rods 52 connected thereto are extended into the liquid nitrogen. The liquid nitrogen is converted to solid nitrogen 30 since the vaporized nitrogen is evacuated through the exhaust pipe 35. Then, the solid nitrogen is cooled further to a temperature below the melting point by the refrigerator when turned on.

For observation with the ion microscope, the refrigeration is turned on. As compared with dependence on the solid nitrogen alone, this lowers the emitter temperature further by about 20K and consequently raises the brightness of the ion source. The refrigerator may also be turned off to suppress the physical vibration due to the refrigerator when observation is performed with the ion microscope.

### Embodiment 7

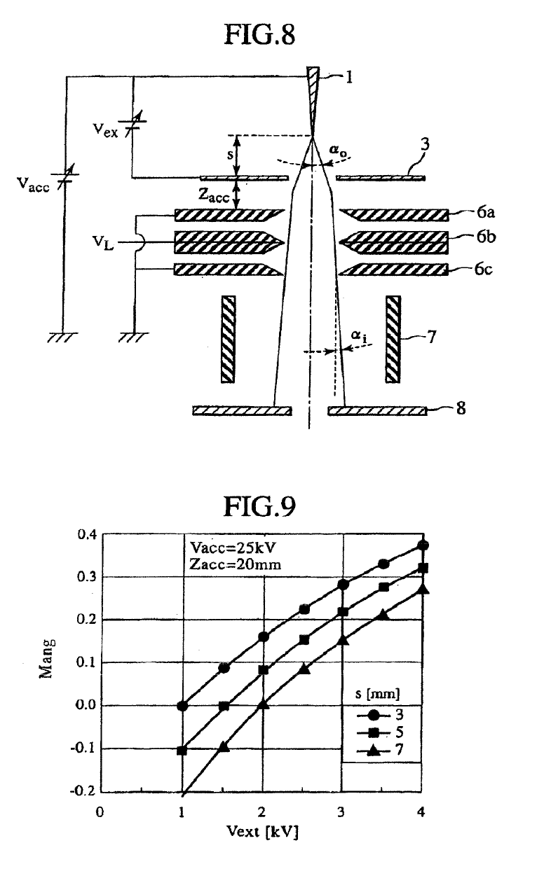

The present embodiment is described below with reference to FIG. 8 and FIG. 9. In the present embodiment, the direction of ion emission from the nano tip of the emitter is checked and the ion emission direction is aligned (adjusted) with the optical axis of the scanning ion microscope while observing a quasi-FIM pattern.

Ions 5 emitted divergently from the emitter 1 pass by the focusing lens (whose lens function is turned off by setting the lens potential V_{L} to the ground potential) and arrive at the movable beam limiting aperture plate 8. The ion beam which has arrived thereat partly passes through the aperture of the movable beam limiting aperture plate 8. Irradiated with the ions which have passed, the specimen 8 emits secondary electrons 15. The secondary electrons 15 are detected by the secondary electron detector 16. Above the movable beam limiting aperture plate 16, the beam deflector/aligner 7 deflects the beam according to a scan signal. A signal. synchronized with this scan signal and the intensity detected by the secondary electron detector 16 are used respectively as the XY signal and Z signal (brightness) to generate a SIM image. This SIM image is monitored on the image display unit 19. The movable beam limiting aperture plate 8 can be moved in a plane perpendicular to the optical axis, allowing fine optical axis or XY adjustment. In addition, the aperture diameter thereof can be selected from various values in a wide range. In the present embodiment, the lens function of the objective lens 12 is adjusted so that the deflection fulcrum of the beam deflector/aligner 7 is projected onto the specimen 14. As a result of this adjustment, although beam scanning by the beam deflector/aligner 7 is performed, the specimen is not scanned by a beam. Rather, the SIM image on the monitor screen shows the angular intensity distribution of emitted ions wherein the X and Y axes represent the emission angles measured toward the X and Y directions respectively. While a FIM image has such a resolution that the ion emission region of the emitter is projected at an atomic level, this SIM image corresponds to an abridged and blurred FIM image which covers an ion radiant solid angle associated with the aperture of the movable beam limiting aperture plate 44. When the scan function of the beam deflector/aligner 7 is turned off, fine XY adjustment and aligner adjustment of the beam deflector/aligner 7 are performed such that the ion emission direction <111> for the quasi-FIM image passes through the center of objective lens 12 and the aperture center of the movable beam limiting aperture plate 8.

In FIG. 8, the focusing lens 8 is an electrostatic lens constituted of three electrodes (6a, 6b and 6c). The two outermost electrodes are at the ground potential. Between the extraction electrode 3 and the focusing lens first electrode 6a, there is an ion accelerating lens function. By using αo to denote the angle of the ions input to this lens and αi to denote the angle of the ions output therefrom, its angular magnification M_{ang} is defined by the following formula.

M_{ang}=(α/αo (5)

If no accelerating lens function is given, that is, the acceleration voltage (V_{acc}) is set equal to the extraction voltage (Vₑₓₜ), M_{ang} becomes equal to 1. FIG. 9 shows an example of curves indicating how M_{ang} is dependent upon Vₑₓₜ if the ion acceleration voltage V_{acc} is fixed to 25 kV and the distance Z_{acc} between the extraction electrode 3 and the focusing lens first electrode 6a is fixed to 20 mm. These curves are plotted for s=3, 5 and 7 mm respectively. Positive and negative M_{ang} values indicate respectively that the output ions are diverged and converged. If the M_{ang} is zero, the output ions are parallel to the optical axis. As understood, the beam diameter at the movable beam limiting aperture plate 8 varies depending on M_{ang} even if the focusing lens is off since the divergence angle of the ions 5 emitted from the emitter is multiplied by a factor of M_{ang} due to the acceleration lens function. That is, the optimum aperture diameter of the movable beam limiting aperture plate 8 varies depending on these values. To adjust the optical axis when the GFIS is mounted to the scanning charged particle microscope or to correct/observe the formation or regeneration of a nano tip on the emitter end, V,acc is set lower. For regular operation of the scanning charged particle microscope after that, Vacc is raised to a certain level.

When adjusting the optical axis of the GFIS in the scanning charged particle microscope (for example, after the emitter tip is repaired), its field emission pattern is monitored by allowing divergently emitted ions to pass the extraction electrode. When using the scanning charged particle microscope to observe a specimen, less divergently emitted ions are allowed to pass through the extraction electrode. By this setting, it is possible to smoothly and efficiently perform high accuracy optical axis adjustment and specimen observation.

While the invention has been described in its preferred embodiments, it is to be understood that the words which have been used are words of description rather than limitation and that changes within the purview of the appended claims may be made without departing from the true scope and spirit of the invention in its broader aspects.

1. A gas field ionization ion source, comprising:
a needle-shaped anode emitter; and
an extraction electrode which forms an electric field by which gas molecules at the apex of the emitter are ionized and extracted;
wherein the diameter of the extraction electrode's aperture for letting extracted ions pass therethrough can be set to any of at least two different values.

2. A gas field ionization ion source, comprising:
a needle-shaped anode emitter; and
an extraction electrode which forms an electric field by which gas molecules at the apex of the emitter are ionized and extracted;
wherein the extraction electrode can be separated into an aperture-forming part having an aperture for letting extracted ions pass therethrough, and a base part on which the aperture-forming part is mounted, and
wherein the aperture-forming part can be withdrawn from and set around the optical axis of ions.

3. A gas field ionization source according to claim 2 wherein, the aperture-forming part is slid with respect to the base part.

4. A gas field ionization ion source, comprising:
a needle-shaped anode emitter; and
an extraction electrode which forms an electric field by which gas molecules at the apex of the emitter are ionized and extracted;
wherein the distance from the apex of the emitter to the extraction electrode can be set to any of at least two different values.

5-6. (canceled)

7. A scanning charged particle microscope, comprising:
a gas field ionization ion source having a needle-shaped anode emitter, and an extraction electrode which forms an electric field by which gas molecules at the apex of the emitter are ionized and extracted, wherein the diameter of the extraction electrode's aperture for letting extracted ions pass therethrough can be set to any of at least two different values;
a lens system by which ions from the ion source are accelerated and focused on a specimen;
a limiting apparatus plate for limiting the ions which are focused on the specimen; and
a charged particle detector to detect charged particles emitted from the specimen.

8. A scanning charged particle microscope, comprising:
a gas field ionization ion source having a needle-shaped anode emitter, and an extraction electrode which forms an electric field by which gas molecules at the apex of the emitter are ionized and extracted, wherein the extraction electrode can be separated into an aperture-forming part having an aperture for letting extracted ions pass therethrough, and a base part on which the aperture-forming part is mounted, wherein the aperture-forming part can be withdrawn from and set around the optical axis of ions;
a lens system by which ions from the ion source are accelerated and focused on a specimen;
a limiting apparatus plate for limiting the ions which are focused on the specimen; and
a charged particle detector to detect charged particles emitted from the specimen.

9. A scanning charged particle microscope according to claim 8 wherein, the aperture-forming part is slid with respect to the base part.

10. A scanning charged particle microscope, comprising:
a gas field ionization ion source having a needle-shaped anode emitter, and an extraction electrode which forms an electric field by which gas molecules at the apex of the emitter are ionized and extracted, wherein the distance from the apex of the emitter to the extraction electrode can be set to any of at least two different values;
a lens system by which ions from the ion source are accelerated and focused on a specimen;
a limiting apparatus plate for limiting the ions which are focused on the specimen; and
a charged particle detector to detect charged particles emitted from the specimen.

11-12. (canceled)

13. A method for adjusting the optical axis of a scanning charged particle microscope comprising:
a gas field ionization ion source having a needle-shaped anode emitter, and an extraction electrode which forms an electric field by which gas molecules at the apex of the emitter are ionized and extracted;
a lens system by which ions from the ion source are accelerated and focused on a specimen;
a limiting apparatus plate for limiting the ions which are focused on the specimen; and
a charged particle detector to detect charged particles emitted from the specimen;
wherein the angular range of emitted ions allowed to pass through the extraction electrode is set larger for adjusting the optical axis of the gas field ionization ion source but smaller than for adjusting the optical axis for using the scanning charged particle microscope to observe the specimen.

14. A method for observing a specimen by using a scanning charged particle microscope comprising:
a gas field ionization ion source having a needle-shaped anode emitter, and an extraction electrode which forms an electric field by which gas molecules at the apex of the emitter are ionized and extracted;
a lens system by which ions from the ion source are accelerated and focused on a specimen;
a limiting apparatus plate for limiting the ions which are focused on the specimen; and
a charged particle detector to detect charged particles emitted from the specimen;
wherein the angular range of emitted ions allowed to pass through the extraction electrode is set larger for adjusting the optical axis of the gas field ionization ion source but smaller than for adjusting the optical axis for using the scanning charged particle microscope to observe the specimen.
